(19) United States
(12) Patent Application Publication
(10) Pub. No.: US 2018/0272425 A1
(43) Pub. Date: Sep. 27, 2018

(54) SILVER-COATED COPPER POWDER AND METHOD FOR PRODUCING SAME

(71) Applicant: DOWA ELECTRONICS MATERIALS CO., LTD., Tokyo (JP)

(72) Inventors: Noriaki Nogami, Tokyo (JP); Hiroshi Kamiga, Tokyo (JP)

(73) Assignee: DOWA ELECTRONICS MATERIALS CO., LTD., Tokyo (JP)

(21) Appl. No.: 15/542,464

(22) PCT Filed: Jan. 6, 2016
(86) PCT No.: PCT/JP2016/000034

§ 371 Date: Jul. 10, 2017

(30) Foreign Application Priority Data
Jan. 13, 2015 (JP) 2015-004008
Jan. 4, 2016 (JP) 2016-000026

(51) Int. Cl. B22F 1/02; H01B 1/02; H01B 1/22; H01L 31/0224

(52) U.S. Cl. CPC B22F 1/025; H01B 1/02; B22F 2301/255; H01L 31/0224; H01B 1/22

(57) ABSTRACT

A silver-coated copper powder obtained by coating the surface of a copper powder, which is obtained by the atomizing method or the like, with 5 wt % or more (with respect to the silver-coated copper powder) of a silver containing layer of silver or a silver compound, is added to a silver supporting solution of a potassium silver cyanide solution (or a potassium silver cyanide solution containing at least one selected from the group consisting of potassium pyrophosphate, boric acid, tripotassium citrate monohydrate, anhydrous citric acid and L-aspartic acid) to cause 0.01 wt % or more (with respect to the silver-coated copper powder) of silver to be supported on the surface of the copper powder coated with the silver containing layer.

### TECHNICAL FIELD

The present invention relates generally to a silver-coated copper powder and a method for producing the same. More specifically, the invention relates to a silver-coated copper powder for use in electrically conductive pastes and so forth, and a method for producing the same.

### BACKGROUND ART

Conventionally, an electrically conductive paste prepared by mixing or compounding a solvent, a resin, a dispersing agent and so forth with an electrically conductive metal powder, such as silver or copper powder, is used for forming electrodes and electric wires of electronic parts by a printing method or the like.

However, silver powder increases the costs of the paste since it is a noble metal although it is a good electrically conductive material having a very low volume resistivity. On the other hand, the storage stability (reliability) of copper powder is inferior to that of silver powder since copper powder is easily oxidized although it is a good electrically conductive material having a low volume resistivity.

In order to solve these problems, as metal powders for use in electrically conductive pastes, there is proposed a silver-coated copper powder wherein the surface of copper powder is coated with silver (see, e.g., Patent Documents 1-2).

### PRIOR ART DOCUMENT(S)

### Patent Document(s)

### Patent Document 1: Japanese Patent Laid-Open No. 2010-174311 (Paragraph Number 0003)

### Patent Document 2: Japanese Patent Laid-Open No. 2010-077495 (Paragraph Number 0006)

### SUMMARY OF THE INVENTION

### Problem to be Solved by the Invention

However, in the silver-coated copper powder disclosed in Patent Documents 1-2, if a part of the surface of copper powder is not coated with silver, the oxidation of copper powder progresses from the part, so that the storage stability (reliability) of the silver-coated copper powder is insufficient.

It is therefore an object of the present invention to eliminate the aforementioned conventional problems and to provide a silver-coated copper powder which has excellent storage stability (reliability), and a method for producing the same.

### Means for Solving the Problem

In order to accomplish the aforementioned object, the inventors have diligently studied and found that it is possible to produce a silver-coated copper powder which has excellent storage stability (reliability), if a copper powder, the surface of which is coated with a silver containing layer, is added to a silver supporting solution to cause silver to be supported on the surface of the copper powder coated with the silver containing layer. Thus, the inventors have made the present invention.

According to the present invention, there is provided a method for producing a silver-coated copper powder, the method comprising the steps of: preparing a copper powder, the surface of which is coated with a silver containing layer; and adding the copper powder to a silver supporting solution to cause silver to be supported on the surface of the copper powder coated with the silver containing layer.

In this method for producing a silver-coated copper powder, the surface, on which silver is caused to be supported, is preferably an exposed surface of the copper powder coated with the silver containing layer. The silver containing layer is preferably a layer of silver or a silver compound. The amount of the silver containing layer with respect to the silver-coated copper powder is preferably 5% by weight or more. The amount of the supported silver with respect to the silver-coated copper powder is preferably 0.01% by weight or more. The silver supporting solution preferably comprises a potassium silver cyanide solution. The potassium silver cyanide solution may contain at least one selected from the group consisting of potassium pyrophosphate, boric acid, tripotassium citrate monohydrate, anhydrous citric acid and L-aspartic acid. The particle diameter (D₅₀ diameter) corresponding to 50% of accumulation in cumulative distribution of the copper powder, which is measured by a laser diffraction particle size analyzer, is preferably in the range of from 0.1 μm to 15 μm.

According to the present invention, there is provided a silver-coated copper powder, wherein silver is supported on an exposed portion of a surface of a copper powder coated with a silver containing layer, and wherein two exothermic peaks appear when the silver-coated copper powder is heated to raise the temperature thereof from room temperature to 400° C. in the atmosphere by means of a thermogravimetry differential thermal analyzer. In this silver-coated copper powder, one of the two exothermic peaks is preferably a main peak which has an exothermic peak temperature of 330 to 370° C., and the other exothermic peak is preferably a sub-peak which has an exothermic peak temperature of 230 to 270° C.

Alternatively, according to the present invention, there is provided a silver-coated copper powder, wherein silver is supported on an exposed portion of a surface of s copper powder coated with s silver containing layer, and wherein the percentage of increase of the weight of the silver-coated copper powder is 0.3% or less at 250° C. and 1.0% or less at 300° C., respectively, when the silver-coated copper powder is heated to raise the temperature thereof from room temperature to 400° C. in the atmosphere by means of a thermogravimetry differential thermal analyzer.

In the above-described silver-coated copper powder, the silver containing layer is preferably a layer of silver or a silver compound. The amount of the silver containing layer with respect to the silver-coated copper powder is preferably 5% by weight or more. The amount of the supported silver with respect to the silver-coated copper powder is preferably 0.01% by weight or more. The particle diameter (D₅₀ diameter) corresponding to 50% of accumulation in cumulative distribution of the copper powder, which is measured by a laser diffraction particle size analyzer, is preferably in the range of from 0.1 μm to 15 μm. The amount of cyanogen in the silver-coated copper powder is preferably in the range of from 10 ppm to 3000 ppm. The content of each of carbon and nitrogen in the silver-coated copper powder is preferably 0.04% by weight or more.

According to the present invention, there is provided an electrically conductive paste wherein the above-described silver-coated copper powder is used as an electric conductor. Alternatively, according to the present invention, there is provided an electrically conductive paste comprising: a solvent; a resin; and the above-described silver-coated copper powder as an electrically conductive powder.

According to the present invention, there is provided a method for producing an electrode for solar cell, the method comprising the steps of: applying the above-described electrically conductive paste on a substrate; and curing the applied electrically conductive paste to form an electrode on the surface of the substrate.

### Effects of the Invention

According to the present invention, it is possible to provide a silver-coated copper powder which has excellent storage stability (reliability), and a method for producing the same. If an electrically conductive paste using the silver-coated copper powder (having silver supported on the surface thereof) is used for forming the busbar electrodes of a solar cell, it is possible to greatly improve the conversion efficiency of the solar cell, and it is possible to suppress the decrease of the conversion efficiency even after a weather resistance test (a reliability test) (for holding the solar cell at a temperature of 85° C. and a humidity of 85% for 24 hours and 48 hours, respectively).

### BRIEF DESCRIPTION OF THE DRAWINGS

FIG. 1 is a graph showing the results in TG-DTA measurement for a silver-coated copper powder in Example 4.

FIG. 2 is a graph showing the results in TG-DTA measurement for a silver-coated copper powder in Example 5.

FIG. 3 is a graph showing the results in TG-DTA measurement for a silver-coated copper powder in Comparative Example 3.

FIG. 4 is a graph showing the results in TG-DTA measurement for a silver-coated copper powder in Comparative Example 4.

FIG. 5 is a graph showing the variation in conversion efficiency of a solar cell produced using each of electrically conductive pastes in Example 7 and Comparative Example 6, with respect to time in a weather resistance test thereof.

### MODE FOR CARRYING OUT THE INVENTION

In the preferred embodiment of a method for producing a silver-coated copper powder according to the present invention, a copper powder, the surface of which is coated with a silver containing layer, is added to a silver supporting solution to cause silver to be supported on the surface of the copper powder coated with the silver containing layer. If silver is thus caused to be supported on (the exposed portion of) the surface of the copper powder coated with the silver containing layer, it is possible to coat the exposed portion (exposed surface) of the copper powder, which is not coated with the silver containing layer, with silver to prevent the oxidation of the copper powder to produce a silver-coated copper powder having excellent storage stability (reliability).

The silver containing layer is preferably a layer of silver or a silver compound. The coating amount of the silver containing layer with respect to the silver-coated copper powder is preferably 5% by weight or more, more preferably in the range of from 7% by weight to 50% by weight, more preferably in the range of from 8% by weight to 40% by weight, and most preferably in the range of from 9% by weight to 20% by weight. If the coating amount of the silver containing layer is less than 5% by weight, it is not preferable since there is a bad influence on the electrical conductivity of the silver-coated copper powder. On the other hand, if the coating amount of the silver containing layer exceeds 50% by weight, it is not preferable since the costs are enhanced by the increase of the amount of silver to be used.

The supported amount of silver with respect to the silver-coated copper powder is preferably 0.01% by weight or more, and more preferably in the range of from 0.05% by weight to 0.7% by weight. If the supported amount of silver is less than 0.01% by weight, the exposed portion of the copper powder of the silver-coated copper powder, which is not coated with silver, is not sufficiently covered with silver. If the supported amount of silver exceeds 0.7% by weight, it is not preferable since the proportion of improvement of the effect of preventing the oxidation of the copper powder with respect to the increased amount of silver is small and since the costs are enhanced.

The silver supporting solution is a solution for causing silver to be supported on a small portion which is not coated with the silver containing layer due to obstructive factor(s), such as oxide(s) on the surface of the copper powder during the coating of the copper powder with the silver containing layer. The silver supporting solution is preferably a solution, which can cause silver to be supported on the exposed portion of the copper powder, the exposed portion being not coated with the silver containing layer, and which does not dissolve the silver containing later therein. The silver supporting solution preferably comprises a solution of a silver cyanide compound, such as a potassium silver cyanide solution. The inventors found that the potassium silver cyanide solution effectively causes silver to be supported on the exposed portion of a copper powder which is not coated with a silver containing layer, although the potassium silver cyanide solution is not suitable for the uniform coating of the surface of a copper powder with silver since a silver coating reaction is easy to be ununiform when it is used for coating the copper powder with silver. The silver supporting solution may be any one of acid, neutral and alkaline solutions. The potassium silver cyanide solution may contain at least one selected from the group consisting of potassium pyrophosphate, boric acid, tripotassium citrate monohydrate, anhydrous citric acid and L-aspartic acid.

With respect to the particle diameter of the copper powder, the particle diameter (D₅₀ diameter) corresponding to 50% of accumulation in cumulative distribution of the copper powder, which is measured by a laser diffraction particle size analyzer (by helos method), is preferably in the range of from 0.1 μm to 15 μm, more preferably in the range of from 0.3 μm to 10 μm, and most preferably in the range of from 1 μm to 5 μm. If the particle diameter (D₅₀ diameter) is less than 0.1 μm, it is not preferable since there is a bad influence on the electrical conductivity of the silver-coated copper powder. On the other hand, if the particle diameter (D₅₀ diameter) exceeds 15 μm, it is not preferable since it is difficult to form fine wires.

The copper powder may be produced by a wet reducing method, an electrolytic method, a gas phase method or the like, and is preferably produced by a so-called atomizing method (such as a gas atomizing method or a water atomizing method) for producing a fine powder by rapidly cooling and solidifying copper, which is melted at a temperature of not lower than the melting temperature thereof, by causing a high-pressure gas or high-pressure water to collide with the molten copper while causing the molten copper to drop from the lower portion of a tundish. In particular, if the copper powder is produced by a so-called water atomizing method for spraying a high-pressure water, it is possible to obtain a copper powder having small particle diameters, so that it is possible to improve the electrical conductivity of an electrically conductive paste due to the increase of the number of contact points between the particles when the copper powder is used for preparing the electrically conductive paste.

As a method for coating the copper powder with the silver containing layer, there may be used a method for depositing silver or a silver compound on the surface of a copper powder by a substitution method utilizing a substitution reaction of copper with silver or by a reduction method using a reducing agent. For example, there may be used a method for depositing silver or a silver compound on the surface of a copper powder while stirring a solution containing the copper powder and silver or the silver compound in a solvent, a method for depositing silver or a silver compound on the surface of a copper powder while stirring a mixed solution prepared by mixing a solution, which contains the copper powder and organic substances in a solvent, with a solution containing silver or the silver compound and organic substances in a solvent, and so forth.

As the solvent, there may be used water, an organic solvent or a mixed solvent thereof. If a solvent prepared by mixing water with an organic solvent is used, it is required to use an organic solvent which is liquid at room temperature (20 to 30° C.), and the mixing ratio of water to the organic solvent may be suitably adjusted in accordance with the used organic solvent. As water used as the solvent, there may be used distilled water, ion-exchanged water, industrial water or the like unless there is the possibility that impurities are mixed therein.

As raw materials of the silver containing layer, silver nitrate having a high solubility with respect to water and many organic solvents is preferably used since it is required to cause silver ions to exist in the solution. In order to carry out a reaction for coating the copper powder with the silver containing layer (silver coating reaction) as uniform as possible, there is preferably used a silver nitrate solution, which is prepared by dissolving silver nitrate in a solvent (water, an organic solvent or a mixed solvent thereof), not solid silver nitrate. The amount of the silver nitrate solution to be used, the concentration of silver nitrate in the silver nitrate solution, and the amount of the organic solvent may be determined in accordance with the amount of the intended silver containing layer.

In order to more uniformly form the silver containing layer, a chelating agent may be added to the solution. As the chelating agent, there is preferably used a chelating agent having a high complex formation constant with respect to copper ions and so forth, so as to prevent the reprecipitation of copper ions and so forth, which are formed as vice-generative products by a substitution reaction of silver ions with metallic copper. In particular, the chelating agent is preferably selected in view of the complex formation constant with respect to copper since the copper powder serving as the core of the silver-coated copper powder contains copper as a main composition element. Specifically, as the chelating agent, there may be used a chelating agent selected from the group consisting of ethylene-diamine-tetraacetic acid (EDTA), triethylene-diamine, and salts thereof.

In order to stably and safely carry out the silver coating reaction, a buffer for pH may be added to the solution. As the buffer for pH, there may be used ammonium carbonate, ammonium hydrogen carbonate, ammonia water, sodium hydrogen carbonate or the like.

When the silver coating reaction is carried out, a solution containing a silver salt is preferably added to a solution in which the copper powder is sufficiently dispersed by stirring the solution after the copper powder is put therein before the silver salt is added thereto. The reaction temperature during this silver coating reaction may be a temperature at which the solidification and evaporation of the reaction solution are not caused. The reaction temperature is set to be preferably 10 to 40° C. and more preferably 15 to 35° C. The reaction time may be set in the range of from 1 minute to 5 hours although it varies in accordance with the coating amount of silver or the silver compound and the reaction temperature.

The preferred embodiment of a silver-coated copper powder according to the present invention is a silver-coated copper powder wherein silver is supported on an exposed portion of a surface of the copper powder coated with the silver containing layer and wherein two exothermic peaks (exothermic peaks appearing in association with the increase of the weight due to oxidation) (a main peak having an exothermic peak temperature of 330 to 370° C. and a sub-peak having an exothermic peak temperature of 230 to 270° C.) appear when the silver-coated copper powder is heated to raise the temperature thereof from room temperature to 400° C. in the atmosphere by means of a thermogravimetry differential thermal analyzer (TG-DTA apparatus). It is considered that the reason why the sub-peak thus appears in addition to the main peak (exothermic peaks appear in two temperature ranges) is that the exothermic peak (sub-peak) due to the aqueous potassium silver cyanide solution in the silver supporting solution, which is used for causing silver to be supported on the surface (exposed surface) of the copper powder coated with the silver containing layer, appears in addition to the exothermic peak (main peak) due to silver nitrate which is used for producing the copper powder coated with the silver containing layer. Furthermore, if silver is not caused to be supported on the surface (exposed surface) of the copper powder coated with the silver containing layer, there is observed only one exothermic peak (main peak) due to silver nitrate which is used for producing the copper powder coated with the silver containing layer.

Alternatively, the preferred embodiment of a silver-coated copper powder according to the present invention is a silver-coated copper powder wherein silver is supported on an exposed portion of a surface of the copper powder coated with the silver containing layer and wherein the percentage of increase of the weight of the silver-coated copper powder is 0.3% or less at 250° C. and 1.0% or less at 300° C., respectively, when the silver-coated copper powder is heated to raise the temperature thereof from room temperature to 400° C. in the atmosphere by means of a thermogravimetry differential thermal analyzer (TG-DTA apparatus). If the percentage of increase of the weight of a silver-coated copper powder is thus low when it is heated in the atmosphere, the silver-coated copper powder has excellent resistance to oxidation and excellent storage stability (reliability) even in such a temperature range that the silver-coated copper powder is used for an electrically conductive paste or the like.

In the above-described preferred embodiment of the silver-coated copper powder, the silver containing layer is preferably a layer of silver or a silver compound. The amount of the silver containing layer with respect to the silver-coated copper powder is preferably 5% by weight or more. The amount of the supported silver with respect to the silver-coated copper powder is preferably 0.01% by weight or more. The particle diameter (D₅₀ diameter) corresponding to 50% of accumulation in cumulative distribution of the copper powder, which is measured by a laser diffraction particle size analyzer, is preferably in the range of from 0.1 μm to 15 μm. The content of each of carbon and nitrogen in the silver-coated copper powder is preferably 0.04% by weight or more. However, if the amount of each of carbon and nitrogen in the silver-coated copper powder is too large, there is some possibility that the electrical conductivity of an electrically conductive paste may be deteriorated when the silver-coated copper powder is used for the electrically conductive paste. Therefore, the content of each of carbon and nitrogen in the silver-coated copper powder is preferably 1% by weight or less, and more preferably 0.3% by weight or less. The amount of cyanogen in the silver-coated copper powder is preferably in the range of from 10 ppm to 3000 ppm. Furthermore, if a solution containing cyanogen is used when the copper powder is coated with the silver containing layer, the silver containing layer is easy to be ununiform. Therefore, when the copper powder is coated with the silver containing layer, a solution containing cyanogen is not preferably used, so that the silver-coated copper powder does not preferably contain cyanogen before silver is supported on the copper powder.

The above-described preferred embodiment of a silver-coated copper powder can be produced by the above-described preferred embodiment of a method for producing a silver-coated copper powder. Furthermore, in the above-described preferred embodiment of a method for producing a silver-coated copper powder, the shape of the copper powder coated with the silver containing layer (the shape of the silver-coated copper powder) may be substantially spherical or flake-shaped. After a crashed copper powder or flake-shaped flat copper powder is coated with the silver containing layer, even if silver is caused to be supported on the exposed portion of the copper powder which is not coated with the silver containing layer, it is possible to produce a silver-coated copper powder which has excellent resistance to oxidation and excellent storage stability (reliability).

### EXAMPLES

Examples of a silver-coated copper powder and a method for producing the same according to the present invention will be described below in detail.

### Example 1

There was prepared a commercially available copper powder produced by atomizing (atomized copper powder SF—Cu (5 μm) produced by Nippon Atomized Metal Powders Corporation). The particle size distribution of this copper powder (before being coated with silver) was derived. As a result, the particle diameter (D₁₀) corresponding to 10% of accumulation in cumulative distribution of the copper powder was 2.26 μm, the particle diameter (D₅₀) corresponding to 50% of accumulation in cumulative distribution of the copper powder was 5.20 μm, and the particle diameter (corresponding to 90% of accumulation in cumulative distribution of the copper powder was 9.32 μm. Furthermore, the particle size distribution of the copper powder was measured by means of a laser diffraction particle size analyzer (Micro-Track Particle Size Distribution Measuring Apparatus MT-3300 produced by Nikkiso Co., Ltd.) for deriving the particle diameters D₁₀, D₅₀ and D₉₀ of the copper powder.

Then, a solution (solution 1) was prepared by dissolving 1470 g of EDTA-4Na (43%) and 1820 g of ammonium carbonate in 2882 g of pure water, and a solution (solution 2) was prepared by adding 235.4 g of an aqueous silver nitrate solution containing 77.8 g of silver to a solution prepared by dissolving 1470 g of EDTA-4Na (43%) and 350 g of ammonium carbonate in 2270 g of pure water.

Then, under a nitrogen atmosphere, 700 g of the above-described copper powder was added to the solution 1, and the temperature of the solution was raised to 35° C. while the solution was stirred. Then, the solution 2 was added to the solution in which the copper powder was dispersed, and the solution was stirred for 30 minutes. Thereafter, the solution was filtered, washed with water, and dried to obtain a copper powder coated with silver (a silver-coated copper powder).

Then, 15 g of pure water (25° C.) was added to 10 g of the silver-coated copper powder thus obtained, and 1.67 g of a silver supporting solution was added thereto to allow a reaction while being stirred for 60 minutes by means of a stirrer. Thereafter, it was filtrated by Nutsche (suction filter) method while pouring water for extrusion thereon. Then, a solid body on the filter paper was washed by pouring pure water thereon, and it was dried at 70° C. for 5 hours by means of a vacuum dryer to obtain a silver-coated copper powder having silver supported on the surface thereof. Furthermore, as the silver supporting solution, there was used 1.67 g of a silver supporting solution distributed from 5.01 g of an aqueous solution containing 100 g/L of potassium silver cyanide, 80 g/L of potassium pyrophosphate and 35 g/L of boric acid. The concentration of each of Ag and Cu in the filtrate was measured by means of an inductively coupled plasma (ICP) mass spectrometer (ICP-MS). As a result, the concentration of Ag was 8 mg/L, and the concentration of Cu was 300 mg/L.

After the silver-coated copper powder (having silver supported on the surface thereof) thus obtained was dissolved in aqua regia, pure water was added thereto to be filtrated to collect silver as silver nitrate. Then, the content of Ag was derived from the collected silver nitride by gravimetric method. As a result, the content of Ag in the silver-coated copper powder was 10.80% by weight. Furthermore, the concentration of Ag in a silver-coated copper powder in Comparative Example 1 which will be described later (a silver-coated copper powder having no silver supported on the surface thereof without being added to a silver supporting solution) was 10.20% by weight. As a result, the amount of silver supported on the surface of the silver-coated copper powder in this example was derived to be 0.60% by weight (=10.80% by weight−10.20% by weight).

Then, the storage stability (reliability) of the silver-coated copper powder (having silver supported on the surface thereof) thus obtained was evaluated by evaluating the high-temperature stability thereof. The evaluation of the high-temperature stability of the silver-coated copper powder (having silver supported on the surface thereof) was carried out as follows. First, a thermogravimetry differential thermal analyzer (TG-DTA) (Thermo Plus EVO2 TG-8120 produced by RIGAKU Corporation) was used for deriving a difference (the weight of the silver-coated copper powder increased by heating) between the weight of the silver-coated copper powder (having silver supported on the surface thereof), which was measured at a temperature of each of 200° C., 250° C., 300° C. and 350° C. when the temperature thereof was raised at a temperature raising rate of 10° C./min from room temperature (25° C.) to 400° C. in the atmosphere, and the weight (40 mg) of the silver-coated copper powder which was measured before the heating. Then, the analyzer was used for deriving a percentage (%) of increase of the weight as a percentage (%) of increase of the difference (the weight of the silver-coated copper powder increased by the heating) with respect to the weight of the silver-coated copper powder before the heating. The high-temperature stability of the silver-coated copper powder (against oxidation) in the atmosphere was evaluated on the basis of the percentage (%) of increase of the weight assuming that all of the weight of the silver-coated copper powder increased by the heating was the weight of the silver-coated copper powder increased by oxidation. As a result, the percentage of increase of the weight at each of 200° C., 250° C., 300° C. and 350° C. was 0.08%, 0.12%, 0.67% and 3.27%, respectively. In the TG-DTA measurement for this silver-coated copper powder, there were observed two exothermic peaks (main peak and sub-peak appearing in association with the increase of the weight due to oxidation), the peaks having an exothermic peak temperature of 260° C. (sub-peak temperature) and an exothermic peak temperature of 352° C. (main peak temperature), respectively.

### Example 2

A silver-coated copper powder having silver supported on the surface thereof was obtained by the same method as that in Example 1, except that an aqueous solution prepared by mixing 0.1 g of tripotassium citrate monohydrate, 0.082 g of anhydrous citric acid, 0.017 g of L-aspartic acid and 2 g of water with 1.67 g of a potassium silver cyanide solution containing 100 g/L of potassium silver cyanide (concentration of acid: 60 g/L) was used as the silver supporting solution. Furthermore, the concentration of each of Ag and Cu in the filtrate was measured by the ICP mass spectrometer (ICP-MS). As a result, the concentration of Ag was 2 mg/L, and the concentration of Cu was 180 mg/L.

The content of Ag in the silver-coated copper powder (having silver supported on the surface thereof) thus obtained was measured by the same method as that in Example 1. As a result, the content of Ag was 10.84% by weight. The amount of silver supported on the surface of the silver-coated copper powder was derived by the same method as that in Example 1. As a result, the amount of silver supported on the surface thereof was 0.64% by weight.

The percentage of increase of the weight of the obtained silver-coated copper powder (having silver supported on the surface thereof) at each of 200° C., 250° C., 300° C. and 350° C. was derived by the same method as that in Example 1. As a result, the percentage of increase of the weight thereof was 0.10%, 0.14%, 0.68% and 3.30%, respectively. In the TG-DTA measurement for this silver-coated copper powder, there were observed two exothermic peaks (main peak and sub-peak appearing in association with the increase of the weight due to oxidation), the peaks having an exothermic peak temperature of 261° C. (sub-peak temperature) and an exothermic peak temperature of 353° C. (main peak temperature), respectively.

### Example 3

A silver-coated copper powder having silver supported on the surface thereof was obtained by the same method as that in Example 1, except that 0.2 mL of a silver supporting solution distributed from 1 g of an aqueous solution containing 100 g/L of potassium silver cyanide was used as the silver supporting solution. Furthermore, the concentration of each of Ag and Cu in the filtrate was measured by the ICP mass spectrometer (ICP-MS). As a result, the concentration of Ag was less than 1 mg/L, and the concentration of Cu was 44 mg/L.

The content of Ag in the silver-coated copper powder (having silver supported on the surface thereof) thus obtained was measured by the same method as that in Example 1. As a result, the content of Ag was 10.50% by weight. The amount of silver supported on the surface of the silver-coated copper powder was derived by the same method as that in Example 1. As a result, the amount of silver supported on the surface thereof was 0.30% by weight.

The percentage of increase of the weight of the obtained silver-coated copper powder (having silver supported on the surface thereof) at each of 200° C., 250° C., 300° C. and 350° C. was derived by the same method as that in Example 1. As a result, the percentage of increase of the weight thereof was 0.13%, 0.15%, 0.80% and 3.03%, respectively. In the TG-DTA measurement for this silver-coated copper powder, there were observed two exothermic peaks (main peak and sub-peak appearing in association with the increase of the weight due to oxidation), the peaks having an exothermic peak temperature of 242° C. (sub-peak temperature) and an exothermic peak temperature of 360° C. (main peak temperature), respectively.

### Example 4

A solution (solution 1) was prepared by dissolving 112.61 g of EDTA-4Na (43%) and 9.10 g of ammonium carbonate in 1440.89 g of pure water, and a solution (solution 2) was prepared by adding 55.96 g of an aqueous silver nitrate solution containing 18.42 g of silver to a solution prepared by dissolving 346.16 g of EDTA-4Na (43%) and 82.89 g of ammonium carbonate in 1551.06 g of pure water.

Then, under a nitrogen atmosphere, 350.00 g of the same copper powder as that in Example 1 was added to the solution 1, and the temperature of the solution was raised to 35° C. while the solution was stirred. Then, the solution 2 was added to the solution in which the copper powder was dispersed, and the solution was stirred for 30 minutes. Thereafter, the solution was filtered, washed with water, and dried to obtain a copper powder coated with silver (a silver-coated copper powder).

Then, a silver-coated copper powder having silver supported on the surface thereof was obtained by the same method as that in Example 1, except that 15 g of pure water (25° C.) was added to 10 g of the silver-coated copper powder (before causing silver to be supported thereon). Furthermore, as the silver supporting solution, there was used 1.67 g of a silver supporting solution distributed from 3.54 g of an aqueous solution containing 100 g/L of potassium silver cyanide, 80 g/L of potassium pyrophosphate and 35 g/L of boric acid. The concentration of each of Ag and Cu in the filtrate was measured by means of the ICP mass spectrometer (ICP-MS). As a result, the concentration of Ag was less than 1 mg/L, and the concentration of Cu was 200 mg/L.

The content of Ag in the silver-coated copper powder (having silver supported on the surface thereof) thus obtained was measured by the same method as that in Example 1. As a result, the content of Ag was 5.68% by weight. The amount of silver supported on the surface of the silver-coated copper powder was derived by the same method as that in Example 1. As a result, the amount of silver supported on the surface thereof was 0.74% by weight.

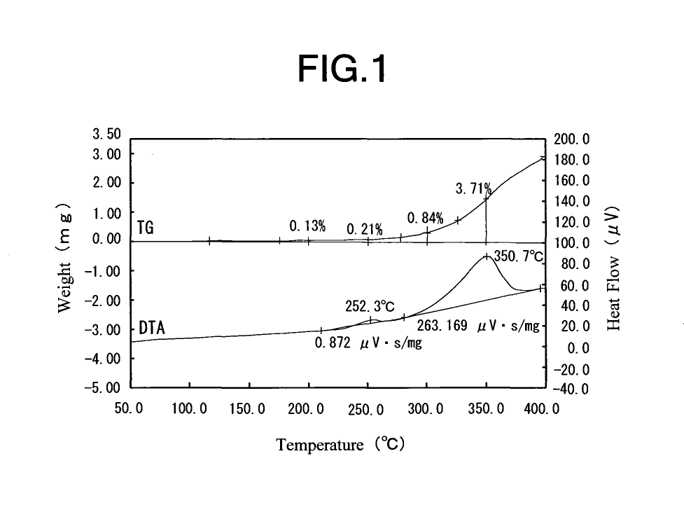

The percentage of increase of the weight of the obtained silver-coated copper powder (having silver supported on the surface thereof) at each of 200° C., 250° C., 300° C. and 350° C. was derived by the same method as that in Example 1. As a result, the percentage of increase of the weight thereof was 0.13%, 0.21%, 0.84% and 3.71%, respectively. As shown in FIG. 1, in the TG-DTA measurement for this silver-coated copper powder, there were observed two exothermic peaks (main peak and sub-peak appearing in association with the increase of the weight due to oxidation), the peaks having an exothermic peak temperature of 252° C. (sub-peak temperature) and an exothermic peak temperature of 351° C. (main peak temperature), respectively.

### Example 5

A solution (solution 1) was prepared by dissolving 2.6 kg of ammonium carbonate in 450 kg of pure water, and a solution (solution 2) was prepared by adding 92 kg of an aqueous silver nitrate solution containing 16.904 kg of silver to a solution prepared by dissolving 319 kg of EDTA-4Na (43%) and 76 kg of ammonium carbonate in 284 kg of pure water.

Then, under a nitrogen atmosphere, 100 kg of the same copper powder as that in Example 1 was added to the solution 1, and the temperature of the solution was raised to 35° C. while the solution was stirred. Then, the solution 2 was added to the solution in which the copper powder was dispersed, and the solution was stirred for 30 minutes. Thereafter, the solution was filtered, washed with water, and dried to obtain a copper powder coated with silver (a silver-coated copper powder).

Then, a silver-coated copper powder having silver supported on the surface thereof was obtained by the same method as that in Example 1, except that 10.5 g of pure water (25° C.) was added to 7 g of the silver-coated copper powder (before causing silver to be supported thereon). Furthermore, as the silver supporting solution, there was used 1.17 g of a silver supporting solution distributed from 2.34 g of an aqueous solution containing 100 g/L of potassium silver cyanide, 80 g/L of potassium pyrophosphate and 35 g/L of boric acid. The concentration of each of Ag and Cu in the filtrate was measured by means of the ICP mass spectrometer (ICP-MS). As a result, the concentration of Ag was 2 mg/L, and the concentration of Cu was 76 mg/L.

The content of Ag in the silver-coated copper powder (having silver supported on the surface thereof) thus obtained was measured by the same method as that in Example 1. As a result, the content of Ag was 15.66% by weight. The amount of silver supported on the surface of the silver-coated copper powder was derived by the same method as that in Example 1. As a result, the amount of silver supported on the surface thereof was 0.59% by weight.

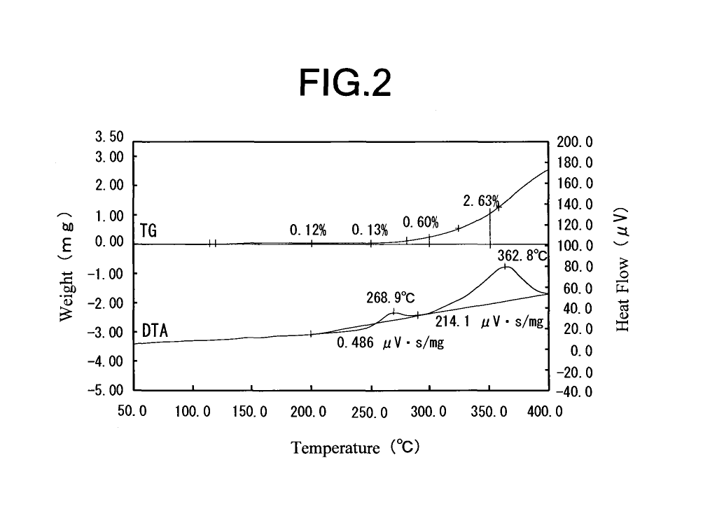

The percentage of increase of the weight of the obtained silver-coated copper powder (having silver supported on the surface thereof) at each of 200° C., 250° C., 300° C. and 350° C. was derived by the same method as that in Example 1. As a result, the percentage of increase of the weight thereof was 0.12%, 0.13%, 0.60% and 2.63%, respectively. As shown in FIG. 2, in the TG-DTA measurement for this silver-coated copper powder, there were observed two exothermic peaks (main peak and sub-peak appearing in association with the increase of the weight due to oxidation), the peaks having an exothermic peak temperature of 269° C. (sub-peak temperature) and an exothermic peak temperature of 363° C. (main peak temperature), respectively.

### Example 6

There was prepared a commercially available copper powder produced by atomizing (atomized copper powder SF—Cu (10 μm) produced by Nippon Atomized Metal Powders Corporation). The particle size distribution of this copper powder was derived by the same method as that in Example 1. As a result, the particle diameter D₁₀ of the copper powder was 3.4 μm, the particle diameter D₅₀ of the copper powder was 8.3 μm, and the particle diameter D₉₀ of the copper powder was 15.8 μm.

Then, a solution (solution 1) was prepared by dissolving 112.6 g of EDTA-4Na (43%) and 9.1 g of ammonium carbonate in 1440 g of pure water, and a solution (solution 2) was prepared by adding 120.9 g of an aqueous silver nitrate solution containing 38.9 g of silver to a solution prepared by dissolving 735 g of EDTA-4Na (43%) and 175 g of ammonium carbonate in 1134 g of pure water.

Then, under a nitrogen atmosphere, 350 g of the above-described copper powder was added to the solution 1, and the temperature of the solution was raised to 35° C. while the solution was stirred. Then, the solution 2 was added to the solution in which the copper powder was dispersed, and the solution was stirred for 30 minutes. Thereafter, the solution was filtered, washed with water, and dried to obtain a copper powder coated with silver (a silver-coated copper powder).

Then, 35 g of pure water (25° C.) was added to 20 g of the silver-coated copper powder thus obtained, and 2.95 mL of a silver supporting solution was added thereto to allow a reaction while being stirred for 60 minutes by means of a stirrer. Thereafter, it was filtrated by Nutsche (suction filter) method while pouring water for extrusion thereon. Then, a solid body on the filter paper was washed by pouring pure water thereon, and it was dried at 70° C. for 5 hours by means of a vacuum dryer to obtain a silver-coated copper powder having silver supported on the surface thereof. Furthermore, as the silver supporting solution, there was used 2.95 mL of a silver supporting solution distributed from an aqueous solution containing 100 g/L of potassium silver cyanide, 80 g/L of potassium pyrophosphate and 35 g/L of boric acid. The concentration of each of Ag and Cu in the filtrate was measured by means of an inductively coupled plasma (ICP) mass spectrometer (ICP-MS). As a result, the concentration of Ag was 2 mg/L, and the concentration of Cu was 65 mg/L.

After the silver-coated copper powder (having silver supported on the surface thereof) thus obtained was dissolved in aqua regia, pure water was added thereto to be filtrated to collect silver as silver nitrate. Then, the content of Ag was derived from the collected silver nitride by gravimetric method. As a result, the content of Ag in the silver-coated copper powder was 10.90% by weight. Furthermore, the concentration of Ag in a silver-coated copper powder in Comparative Example 5 which will be described later (a silver-coated copper powder having no silver supported on the surface thereof without being added to a silver supporting solution) was 10.24% by weight. As a result, the amount of silver supported on the surface of the silver-coated copper powder in this example was derived to be 0.66% by weight (=10.90% by weight−10.24% by weight).

The percentage of increase of the weight of the obtained silver-coated copper powder (having silver supported on the surface thereof) at each of 200° C., 250° C., 300° C. and 350° C. was derived by the same method as that in Example 1. As a result, the percentage of increase of the weight thereof was 0.06%, 0.09%, 0.56% and 2.85%, respectively. In the TG-DTA measurement for this silver-coated copper powder, there were observed two exothermic peaks (main peak and sub-peak appearing in association with the increase of the weight due to oxidation), the peaks having an exothermic peak temperature of 253° C. (sub-peak temperature) and an exothermic peak temperature of 349° C. (main peak temperature), respectively.

### Comparative Example 1

The content of Ag in the silver-coated copper powder (having no silver supported on the surface thereof without being added to the silver supporting solution) obtained in Example 1 was measured by the same method as that in Example 1. As a result, the content of Ag was 10.20% by weight. The percentage of increase of the weight of the silver-coated copper powder at each of 200° C., 250° C., 300° C. and 350° C. was derived by the same method as that in Example 1. As a result, the percentage of increase of the weight thereof was 0.17%, 0.43%, 1.19% and 3.70%, respectively. In the TG-DTA measurement for this silver-coated copper powder, there was observed one exothermic peak (a peak appearing in association with the increase of the weight due to oxidation), the peak having an exothermic peak temperature of 348° C.

### Comparative Example 2

As a different lot from that in Comparative Example 1, the content of Ag in the silver-coated copper powder (having no silver supported on the surface thereof without being added to the silver supporting solution) obtained in Example 1 was measured by the same method as that in Example 1. As a result, the content of Ag was 10.90% by weight. The percentage of increase of the weight of the silver-coated copper powder at each of 200° C., 250° C., 300° C. and 350° C. was derived by the same method as that in Example 1. As a result, the percentage of increase of the weight thereof was 0.16%, 0.46%, 1.27% and 3.80%, respectively. In the TG-DTA measurement for this silver-coated copper powder, there was observed one exothermic peak (a peak appearing in association with the increase of the weight due to oxidation), the peak having an exothermic peak temperature of 349° C.

### Comparative Example 3

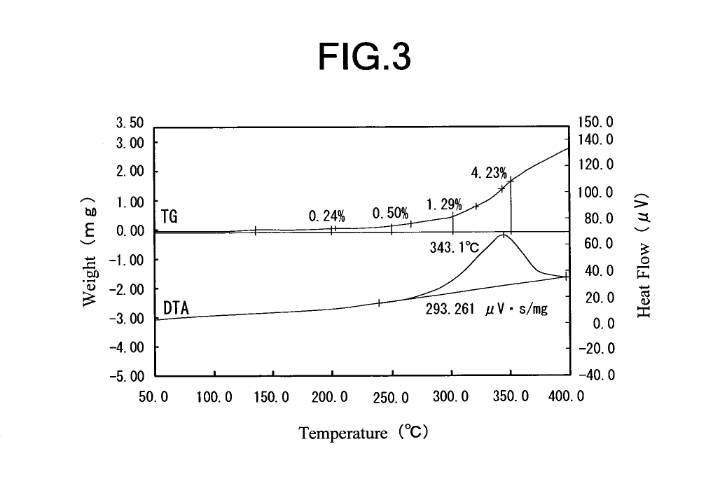

The content of Ag in the silver-coated copper powder (having no silver supported on the surface thereof without being added to the silver supporting solution) obtained in Example 4 was measured by the same method as that in Example 1. As a result, the content of Ag was 4.94% by weight. The percentage of increase of the weight of the silver-coated copper powder at each of 200° C., 250° C., 300° C. and 350° C. was derived by the same method as that in Example 1. As a result, the percentage of increase of the weight thereof was 0.24%, 0.50%, 1.29% and 4.23%, respectively. As shown in FIG. 3, in the TG-DTA measurement for this silver-coated copper powder, there was observed one exothermic peak (a peak appearing in association with the increase of the weight due to oxidation), the peak having an exothermic peak temperature of 343° C.

### Comparative Example 4

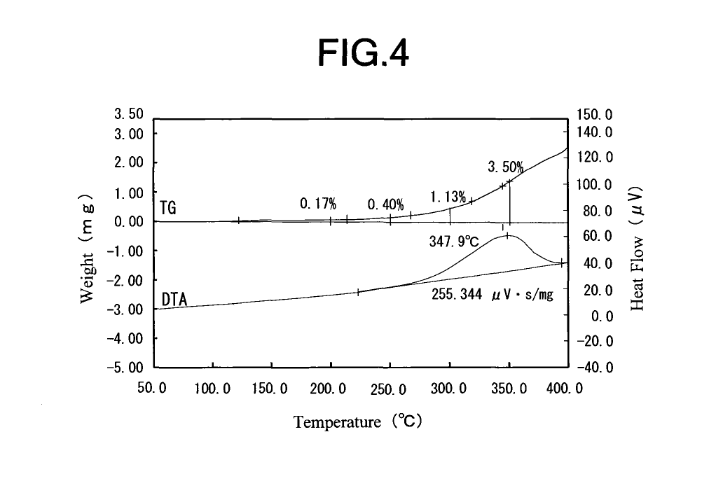

The content of Ag in the silver-coated copper powder (having no silver supported on the surface thereof without being added to the silver supporting solution) obtained in Example 5 was measured by the same method as that in Example 1. As a result, the content of Ag was 15.07% by weight. The percentage of increase of the weight of the silver-coated copper powder at each of 200° C., 250° C., 300° C. and 350° C. was derived by the same method as that in Example 1. As a result, the percentage of increase of the weight thereof was 0.17%, 0.40%, 1.13% and 3.50%, respectively. As shown in FIG. 4, in the TG-DTA measurement for this silver-coated copper powder, there was observed one exothermic peak (a peak appearing in association with the increase of the weight due to oxidation), the peak having an exothermic peak temperature of 348° C.

### Comparative Example 5

The content of Ag in the silver-coated copper powder (having no silver supported on the surface thereof without being added to the silver supporting solution) obtained in Example 6 was measured by the same method as that in Example 1. As a result, the content of Ag was 10.24% by weight. The percentage of increase of the weight of the silver-coated copper powder at each of 200° C., 250° C., 300° C. and 350° C. was derived by the same method as that in Example 1. As a result, the percentage of increase of the weight thereof was 0.12%, 0.42%, 1.03% and 3.06%, respectively. In the TG-DTA measurement for this silver-coated copper powder, there was observed one exothermic peak (a peak appearing in association with the increase of the weight due to oxidation), the peak having an exothermic peak temperature of 348° C.

The producing conditions and characteristics of the silver-coated copper powders obtained in these examples and comparative examples are shown in Tables 1-2.

TABLE 1

| | |
|---|---|
| | Silver-coated |
| Filtrate | copper powder |

| | Ag | Cu | Ag | Supported |
|---|---|---|---|---|
| | (mg/L) | (mg/L) | (wt %) | Ag (wt %) |
| Ex. 1 | 8 | 300 | 10.80 | 0.60 |
| Ex. 2 | 2 | 180 | 10.84 | 0.64 |
| Ex. 3 | <1 | 44 | 10.50 | 0.30 |
| Ex. 4 | <1 | 200 | 5.68 | 0.74 |
| Ex. 5 | 2 | 76 | 15.66 | 0.59 |
| Ex. 6 | 2 | 65 | 10.90 | 0.66 |
| Comp. 1 | — | — | 10.20 | 0 |
| Comp. 2 | — | — | 10.90 | 0 |
| Comp. 3 | — | — | 4.94 | 0 |
| Comp. 4 | — | — | 15.07 | 0 |
| Comp. 5 | — | — | 10.24 | 0 |

TABLE 2

| | | | | | Peak | |
|---|---|---|---|---|---|---|
| | Percentage of Increase | | | | Temperature | |
| | of Weight (%) | | | | (° C.) | |
| | 200° C. | 250° C. | 300° C. | 350° C. | main | sub |
| Ex. 1 | 0.08 | 0.12 | 0.67 | 3.27 | 352 | 260 |
| Ex. 2 | 0.10 | 0.14 | 0.68 | 3.30 | 353 | 261 |
| Ex. 3 | 0.13 | 0.15 | 0.80 | 3.03 | 360 | 242 |
| Ex. 4 | 0.13 | 0.21 | 0.84 | 3.71 | 351 | 252 |
| Ex. 5 | 0.12 | 0.13 | 0.60 | 2.63 | 363 | 269 |
| Ex. 6 | 0.06 | 0.09 | 0.56 | 2.85 | 349 | 253 |
| Comp. 1 | 0.17 | 0.43 | 1.19 | 3.70 | 348 | — |
| Comp. 2 | 0.16 | 0.46 | 1.27 | 3.80 | 349 | — |
| Comp. 3 | 0.24 | 0.50 | 1.29 | 4.23 | 343 | — |
| Comp. 4 | 0.17 | 0.40 | 1.13 | 3.50 | 348 | — |
| Comp. 5 | 0.12 | 0.42 | 1.03 | 3.06 | 348 | — |

As shown in Tables 1-2, in the silver-coated copper powder having silver supported on the surface (exposed surface) of the copper powder coated with the silver containing layer in each of Examples 1-6, the percentage of increase of the weight thereof after heating in the atmosphere can be smaller than that of the silver-coated copper powder having no silver supported on the surface thereof in each of Comparative Examples 1-5. Therefore, it can be seen that it is possible to improve the resistance to oxidation, so that the storage stability (reliability) thereof is excellent. Furthermore, as Comparative Example 4, even if the content of Ag in the silver-coated copper powder is larger than that in each of Examples 1-3, the percentage of increase of the weight thereof in Comparative Example 4 is higher than that in each of Examples 1-3 when it is heated in the atmosphere. Therefore, it can be seen that it is not possible to obtain a silver-coated copper powder, which has improved resistance to oxidation and which has excellent storage stability (reliability), by increasing only the content of Ag in the silver-coated copper powder.

The filtrate obtained during the production of the silver-coated copper powder having silver supported on the surface thereof in each of the examples has a very low concentration of Ag and a high concentration of Cu, so that it is supposed that silver is selectively supported on the exposed portion of the copper powder, which is not coated with silver. Therefore, the exposed portion of the copper powder, which is not coated with silver, can be covered with a very small amount of silver to improve the resistance to oxidation of the silver-coated copper powder, so that it is possible to produce a silver-coated copper powder having excellent storage stability (reliability).

### Comparative Example 6 and Example 7

As Comparative Example 6, a silver-coated copper powder (having no silver supported on the surface thereof without being added to the silver supporting solution) was obtained by the same method as that in Example 1. As Example 7, a silver-coated copper powder having silver supported on the surface thereof was obtained by the same method as that in Example 1. The concentration of Ag in each of the silver-coated copper powders was measured by the same method as that in Example 1. As a result, the content of Ag in the silver-coated copper powder in Comparative Example 6 was 10.14% by weight, and the content of Ag in the silver-coated copper powder in Example 7 was 10.77% by weight. The content of each of carbon, nitrogen and oxygen and the amount of cyanogen in each of the silver-coated copper powders were obtained, and the particle size distribution and BET specific surface area of each of the silver-coated copper powders were obtained. Furthermore, with respect to the silver-coated copper powders in Comparative Example 6 and Example 7, the TG-DTA measurement was carried out by the same method as than in Example 1. As a result, in the silver-coated copper powder in Comparative Example 6, one exothermic peak was observed similar to Comparative Example 1. In the silver-coated copper powder in Example 7, two exothermic peaks were observed similar to Example 1.

The content of carbon was measured by means of a carbon/sulfur analyzer (EMIA-810W produced by HORIBA, Ltd.), and the content of each of nitrogen and oxygen was measured by an oxygen/nitrogen/hydrogen analyzer (produced LECO, Ltd.). As a result, in the silver-coated copper powder in Comparative Example 6, the content of carbon was 0.02% by weight, the content of nitrogen was 0.007% by weight, and the content of oxygen was 0.08% by weight. In the silver-coated copper powder in Example 7, the content of carbon was 0.13% by weight, the content of nitrogen was 0.112% by weight, and the content of oxygen was 0.10% by weight.

The amount of cyanogen (CN—) was obtained by carrying out the pretreatment (all cyanogen) of a liquid, which was prepared by distilling 250 mL of water containing 1 g of the weighed silver-coated copper powder in a retort, and analyzing the pretreated liquid by the pyridine-pyrazolone absorption spectrophotometry, on the basis of JIS K0102. As a result, no cyanogen was detected in the silver-coated copper powder in Comparative Example 6, and the amount of cyanogen in the silver-coated copper powder in Example 7 was 1400 ppm.

The particle size distribution was measured by means of a laser diffraction particle size analyzer (Micro-Track Particle Size Distribution Measuring Apparatus MT-3300 produced by Nikkiso Co., Ltd.). As a result, with respect to the silver-coated copper powder in Comparative Example 6, the particle diameter (D₁₀) corresponding to 10% of accumulation in cumulative distribution was 2.5 μm, the particle diameter (D₅₀) corresponding to 50% of accumulation in cumulative distribution was 5.2 μm, and the particle diameter (D₉₀) corresponding to 90% of accumulation in cumulative distribution was 10.1 μm. With respect to the silver-coated copper powder in Example 7, the particle diameter (D₁₀) corresponding to 10% of accumulation in cumulative distribution was 2.5 μm, the particle diameter (D₅₀) corresponding to 50% of accumulation in cumulative distribution was 5.0 μm, and the particle diameter (D₉₀) corresponding to 90% of accumulation in cumulative distribution was 10.0 μm.

The BET specific surface area was measured by means of a BET specific surface area measuring apparatus (4-Sorb US produced by Yuasa Ionics Co., Ltd.) using the single point BET method. As a result, the BET specific surface area of the silver-coated copper powder in Comparative Example 6 was 0.31 m²/g, and the BET specific surface area of the silver-coated copper powder in Example 7 was 0.29 m²/g.

These results are shown in Table 3.

TABLE 3

| | | | | | | Particle Size | | | |
|---|---|---|---|---|---|---|---|---|---|
| | | | | | | Distribution | | | |
| | Ag | C | N | O | CN- | (μm) | | | BET |
| | (wt %) | (wt %) | (wt %) | (wt %) | (ppm) | D₁₀ | D₅₀ | D₉₀ | (cm²/g) |
| Comp. 6 | 10.14 | 0.02 | 0.007 | 0.08 | 0 | 2.5 | 5.2 | 10.1 | 0.31 |
| Ex. 7 | 10.77 | 0.13 | 0.112 | 0.1 | 1400 | 2.5 | 5.0 | 10.0 | 0.29 |

As can be seen from Table 3, in the silver-coated copper powder (having silver supported on the surface thereof) in Example 7, the contents of carbon and nitrogen were increased although the content of oxygen is hardly varied, in comparison with the silver-coated copper powder (having no silver supported on the surface thereof without being added to a silver supporting solution). In the silver-coated copper powder in Example 7, even if it is washed with before being dried during the production thereof, cyanogen remains, so that the silver-coated copper powder contains cyanogen, although no cyanogen is detected in the silver-coated copper powder in Comparative Example 6.

After 87.0% by weight of the silver-coated copper powder in each of Comparative Example 6 and Example 7, 3.8% by weight of an epoxy resin (JER1256 produced by Mitsubishi Chemicals Corporation), 8.6% by weight of butyl carbitol acetate (produced by Wako Pure Chemical Industries, Ltd.) serving as a solvent, 0.5% by weight of a curing agent (M-24 produced by Ajinomoto Fine-Techno Co., Inc.) and 0.1% by weight of oleic acid (produced by Wako Pure Chemical Industries, Ltd.) serving as a dispersing agent were mixed (preliminarily kneaded) by means of a planetary centrifugal vacuum degassing mixer (Awatori Rentaro produced by Thinky Corporation), the obtained mixture was kneaded by means of a three-roll mill (EXAKT 80S produced by Otto Hermann Inc.) to obtain an electrically conductive paste 1.

In addition, 45 L of industrial ammonia water was added to 502.7 L of a silver nitrate solution containing 21.4 g/L of silver ions to form a silver amine complex solution. The pH of the formed silver amine complex solution was adjusted by adding 8.8 L of a sodium hydroxide solution containing 100 g/L of sodium hydroxide thereto. This solution was distilled by adding 462 L of water thereto, and 48 L of industrial formalin serving as a reducing agent was added thereto. Immediately thereafter, 121 g of a stearic acid emulsion containing 16% by weight of stearic acid was added thereto. After a silver slurry thus obtained was filtered and washed with water, it was dried to obtain 21.6 kg of a silver powder. After the surface smoothing treatment of this silver powder was carried out by means of a Henschel mixer (high-speed mixer), the classification thereof was carried out to remove large aggregates of silver being larger than 11 μm.

Then, after 85.4% by weight of the silver powder thus obtained, 1.2% by weight of ethyl cellulose (produced by Wako Pure Chemical Industries, Ltd.), 7.9% by weight of a solvent (a mixed solvent containing texanol (produced by JMC Co., Ltd.) and butyl carbitol acetate (produced by Wako Pure Chemical Industries, Ltd.) at 1:1), and 1.5% by weight of a glass frit (ASF-1898B produced by Asahi Glass Co., Ltd.) and 3.2% by weight of tellurium dioxide (produced by Wako Pure Chemical Industries, Ltd.) serving as additives were mixed (preliminarily kneaded) by means of a planetary centrifugal vacuum degassing mixer (Awatori Rentaro produced by Thinky Corporation), the obtained mixture was kneaded by means of a three-roll mill (EXAKT 80S produced by Otto Hermann Inc.) to obtain an electrically conductive paste 2.

Then, two silicon wafers (produced by E&M Co., Ltd, 80 Ω/square, 6 inches monocrystal) were prepared. After an aluminum paste (ALSOLAR 14-7021 produced by Toyo Aluminum K.K.) was printed on the backside of each of the silicon wafers by means of a screen printing machine (MT-320T produced by Micro-tech Co., Ltd.), it was dried at 200° C. for 10 minutes by means of a hot air type dryer. Then, after the above-described electrically conductive paste 2 was printed on the surface (front side) of each of the silicon wafers in the shape of 100 finger electrodes, each having a width of 50 μm, by means of the screen printing machine (MT-320T produced by Micro-tech Co., Ltd.), it was dried at 200° C. for 10 minutes by means of the hot air type dryer, and then, it was fired at a peak temperature of 820° C. for an in-out time of 21 seconds in a fast firing IR furnace (Fast Firing Test Four-Chamber Furnace produced by NGK Insulators Ltd.). Thereafter, the electrically conductive paste 1 (the electrically conductive paste 1 produced from the silver-coated copper powder in each of Comparative Example 6 and Example 7) was printed on the surface (front side) of each of the silicon wafers in the shape of three busbar electrodes, each having a width of 1.3 mm, by means of the screen printing machine (MT-320T produced by Micro-tech Co., Ltd.), and then, it was dried at 200° C. for 40 minutes by means of the hot air type dryer and cured to produce a solar cell.

Then, a battery characteristic test was carried out by irradiating the above-described solar cell with pseudo sunlight having a light irradiation energy of 100 mWcm² by means of a xenon lamp of a solar simulator (produced by Wacom Electric Co., Ltd.). As a result, the conversion efficiency Eff of the solar cell produced using the electrically conductive paste in each of Comparative Example 6 and Example 7 was 18.34% and 19.94%, respectively.

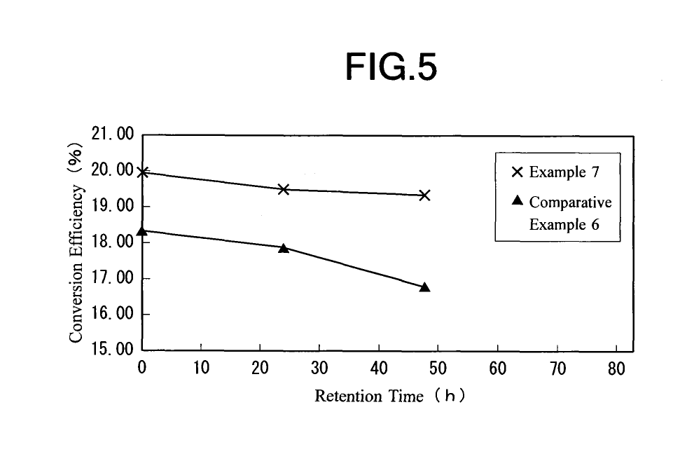

As the weather resistance test (reliability test), each of the above-described solar cells was put in a temperature and humidity testing chamber which was set at a temperature of 85° C. and a humidity of 85%, and the conversion efficiency Eff thereof was derived after 24 hours and 48 hours, respectively. As a result, the conversion efficiency Eff of the solar cell produced using the electrically conductive paste in Comparative Example 6 was 17.87% after 24 hours and 16.79% after 48 hours, respectively. The conversion efficiency Eff of the solar cell produced using the electrically conductive paste in Example 7 was 19.49% after 24 hours and 19.36% after 48 hours, respectively. These results are shown in FIG. 5.

It can be seen from these results that it is possible to greatly improve the conversion efficiency Eff of the solar cell and it is possible to suppress the decrease of the conversion efficiency even after the weather resistance test, if the electrically conductive paste using the silver-coated copper powder having silver supported on the surface thereof is used for forming the busbar electrodes of the solar cell. Thus, if an electrically conductive paste using a silver-coated copper powder (having silver supported on the surface thereof) according to the present invention is used for forming the busbar electrodes of the solar cell, it is possible to improve the conversion efficiency of the current solar cell while maintaining practical reliability thereof.

### INDUSTRIAL APPLICABILITY

The silver-coated copper powder according to the present invention can be utilized for producing an electrically conductive paste for use in electrically conductive patterns of circuit boards, and electronic parts, such as electrodes and circuits of substrates of solar cells and so forth.

1. A method for producing a silver-coated copper powder, the method comprising the steps of:
preparing a copper powder, the surface of which is coated with a silver containing layer; and
adding the copper powder to a silver supporting solution to cause silver to be supported on the surface of the copper powder coated with the silver containing layer.

2. A method for producing a silver-coated copper powder as set forth in claim 1, wherein said surface, on which silver is caused to be supported, is an exposed surface of said copper powder coated with said silver containing layer.

3. A method for producing a silver-coated copper powder as set forth in claim 1, wherein said silver containing layer is a layer of silver or a silver compound.

4. A method for producing a silver-coated copper powder as set forth in claim 1, wherein the amount of said silver containing layer with respect to said silver-coated copper powder is not less than 5% by weight.

5. A method for producing a silver-coated copper powder as set forth in claim 1, wherein the amount of the supported silver with respect to said silver-coated copper powder is not less than 0.01% by weight.

6. A method for producing a silver-coated copper powder as set forth in claim 1, wherein said silver supporting solution comprises a potassium silver cyanide solution.

7. A method for producing a silver-coated copper powder as set forth in claim 6, wherein said potassium silver cyanide solution contains at least one selected from the group consisting of potassium pyrophosphate, boric acid, tripotassium citrate monohydrate, anhydrous citric acid and L-aspartic acid.

8. A method for producing a silver-coated copper powder as set forth in claim 1, wherein a particle diameter (D₅₀ diameter) corresponding to 50% of accumulation in cumulative distribution of said copper powder, which is measured by a laser diffraction particle size analyzer, is in the range of from 0.1 μm to 15 μm.

9. A silver-coated copper powder,
wherein silver is supported on an exposed portion of a surface of a copper powder coated with a silver containing layer, and
wherein two exothermic peaks appear when the silver-coated copper powder is heated to raise the temperature thereof from room temperature to 400° C. in the atmosphere by means of a thermogravimetry differential thermal analyzer.

10. A silver-coated copper powder as set forth in claim 9, wherein one of said two exothermic peaks is a main peak which has an exothermic peak temperature of 330 to 370° C., and the other exothermic peak is a sub-peak which has an exothermic peak temperature of 230 to 270° C.

11. A silver-coated copper powder,
wherein silver is supported on an exposed portion of a surface of a copper powder coated with a silver containing layer, and
wherein the percentage of increase of the weight of the silver-coated copper powder is 0.3% or less at 250° C. and 1.0% or less at 300° C., respectively, when the silver-coated copper powder is heated to raise the temperature thereof from room temperature to 400° C. in the atmosphere by means of a thermogravimetry differential thermal analyzer.

12. A silver-coated copper powder as set forth in claim 9, wherein said silver containing layer is a layer of silver or a silver compound.

13. A silver-coated copper powder as set forth in claim 9, wherein the amount of said silver containing layer with respect to said silver-coated copper powder is not less than 5% by weight.

14. A silver-coated copper powder as set forth in claim 9, wherein the amount of the supported silver with respect to said silver-coated copper powder is not less than 0.01% by weight.

15. A silver-coated copper powder as set forth in claim 9, wherein a particle diameter (D₅₀ diameter) corresponding to 50% of accumulation in cumulative distribution of said copper powder, which is measured by a laser diffraction particle size analyzer, is in the range of from 0.1 μm to 15 μm.

16. A silver-coated copper powder as set forth in claim 9, wherein the amount of cyanogen in said silver-coated copper powder is in the range of from 10 ppm to 3000 ppm.

17. A silver-coated copper powder as set forth in claim 9, wherein the content of each of carbon and nitrogen in said silver-coated copper powder is not less than 0.04% by weight.

18. An electrically conductive paste wherein a silver powder as set forth in claim 9 is used as an electric conductor.

19. An electrically conductive paste comprising:
a solvent;
a resin; and
a silver powder as set forth in claim 9 as an electrically conductive powder.

20. A method for producing an electrode for solar cell, the method comprising the steps of:
applying an electrically conductive paste as set forth in claim 18, on a substrate; and
curing the electrically conductive paste to form an electrode on the surface of the substrate.
